(19) United States
(12) Patent Application Publication
(10) Pub. No.: US 2025/0033156 A1
(43) Pub. Date: Jan. 30, 2025

(54) SWAPPER FOR A CLUSTER TOOL

(71) Applicant: Applied Materials, Inc., Santa Clara, CA (US)

(72) Inventors: Upendra UMMETHALA, Santa Clara, CA (US); Praveen CHORAGUDI, Singapore (SG); Kaushik ALAYAVALLI, Sunnyvale, CA (US); Bhawesh AGRAWAL, Bangalore (IN)

(21) Appl. No.: 18/784,593

(22) Filed: Jul. 25, 2024

Related U.S. Application Data
(60) Provisional application No. 63/529,483, filed on Jul. 28, 2023.

(51) Int. Cl. B23Q 7/14; B23Q 11/14

(52) U.S. Cl. CPC B23Q 7/1431; B23Q 11/143

(57) ABSTRACT

A swapper assembly of a cluster tool includes a housing, at least two swappers, and a motor assembly. The at least two swappers are at least partially disposed within and rotatable relative to the housing. Each swapper includes a body, a first arm, and a second arm. The first arm and second arm are rotatable relative to the body. The motor assembly includes at least one motor, and the motor assembly is configured to operate the at least two swappers simultaneously to change the position of the first arm and second arm.

### CROSS-REFERENCE TO RELATED APPLICATIONS

This application claims priority to and the benefit of U.S. Provisional Application No. 63/529,483, filed Jul. 28, 2023. The aforementioned application is incorporated by reference herein in its entirety.

### BACKGROUND

### Field

Embodiments of the present disclosure generally relate to the linear transport of substrates in a cluster tool.

### Description of the Related Art

Cluster tools are used in the manufacturing of semiconductor devices on substrates. Cluster tools have robotic mechanisms that are used to convey substrates between different chambers within the cluster tool. A substrate is placed in a load lock of the cluster tool and then may be transferred between multiple robotic mechanisms before being placed into a processing chamber that deposits or otherwise forms a layer or feature on the surface of the substrate. Additionally, these robotic mechanisms are operated by different motors.

There is a need in the art to directly transfer a substrate from a load lock to a processing chamber. There is also a need in the art to operate multiple robotic mechanisms while reducing the number of motors.

### SUMMARY

In one embodiment, a swapper assembly includes a housing, at least two swappers, and a motor assembly. The at least two swappers are at least partially disposed within and rotatable relative to the housing. Each swapper includes a body, a first arm, a second arm, and wherein the first arm and second arm are rotatable relative to the body. The motor assembly includes a single motor configured to operate the at least two swappers simultaneously to change the position of the first arm and second arm.

In one embodiment, a method of operating a cluster tool includes placing a first substrate on a first arm of a first swapper, the first arm being positioned in a first load lock. The method further includes placing a second substrate on a second arm of the first swapper, the second arm being positioned within a first processing chamber. The method further includes placing a third substrate on a third arm of a second swapper, the third arm being located in a second load lock. The method further includes placing a fourth substrate on a fourth arm of the second swapper, the fourth arm being positioned within a second processing chamber. The method further includes operating the first swapper and the second swapper with a single motor to simultaneously move the first substrate on the first arm into the first processing chamber, the second substrate on the second arm into the first load lock, the third substrate on the third arm into the second processing chamber, and the fourth substrate on the fourth arm into the second load lock.

In one embodiment, a cluster tool includes a first load lock, a second load lock, a first processing chamber, a second processing chamber, and a swapper assembly. The swapper assembly is disposed between the first load lock and the first processing chamber and between the second load lock and the second processing chamber. The swapper assembly includes a housing, a first swapper, and a second swapper. The first swapper is at least partially disposed within the housing and is rotatable relative to the housing. The first swapper includes a first arm and a second arm, wherein the first arm is moveable to convey a first substrate disposed thereon along a first linear trajectory from the first load lock to the first processing chamber, and the second arm is moveable to convey a second substrate disposed thereon along a second linear trajectory from the first processing chamber to the first load lock. The second swapper is at least partially disposed within the housing and is rotatable relative to the housing. The second swapper includes a third arm and a fourth arm, wherein the third arm is moveable to convey a third substrate disposed thereon along a third linear trajectory from the second load lock to the second processing chamber, and the fourth arm is moveable to convey a fourth substrate disposed thereon along a fourth linear trajectory from the second processing chamber to the second load lock. The motor assembly includes one, and only one motor configured to operate the first swapper and second swapper simultaneously to move the first arm and second arm of the first swapper and the third arm and fourth arm of the second swapper.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates a schematic plan view of an exemplary cluster tool, according to embodiments described herein.

FIG. 1B is a schematic partial cross-sectional view of a swapper assembly, according to embodiments described herein.

FIG. 2 is a schematic partial cross-sectional view of a swapper assembly, according to embodiments described herein.

FIG. 3A is a schematic plan view of a cluster tool, according to embodiments described herein.

FIG. 3B is a schematic cross-sectional plan view of an exemplary cluster tool according to embodiments described herein.

FIG. 4 illustrates a flow chart of an exemplary method of operating a cluster tool, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides an apparatus and method for processing substrates using a multi-chamber processing system (e.g., a cluster tool) adapted to process substrates. A cluster tool is a system comprising multiple chambers which perform various functions in the electronic device fabrication process. The cluster tool includes at least two swapping mechanisms operated by the same motor assembly to transfer substrates between two chambers within the cluster tool.

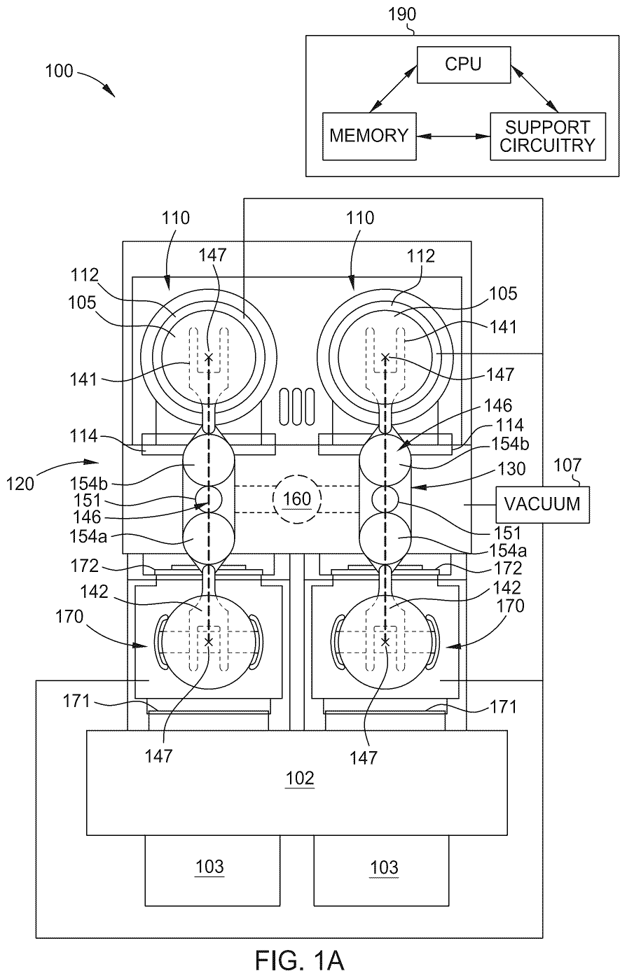

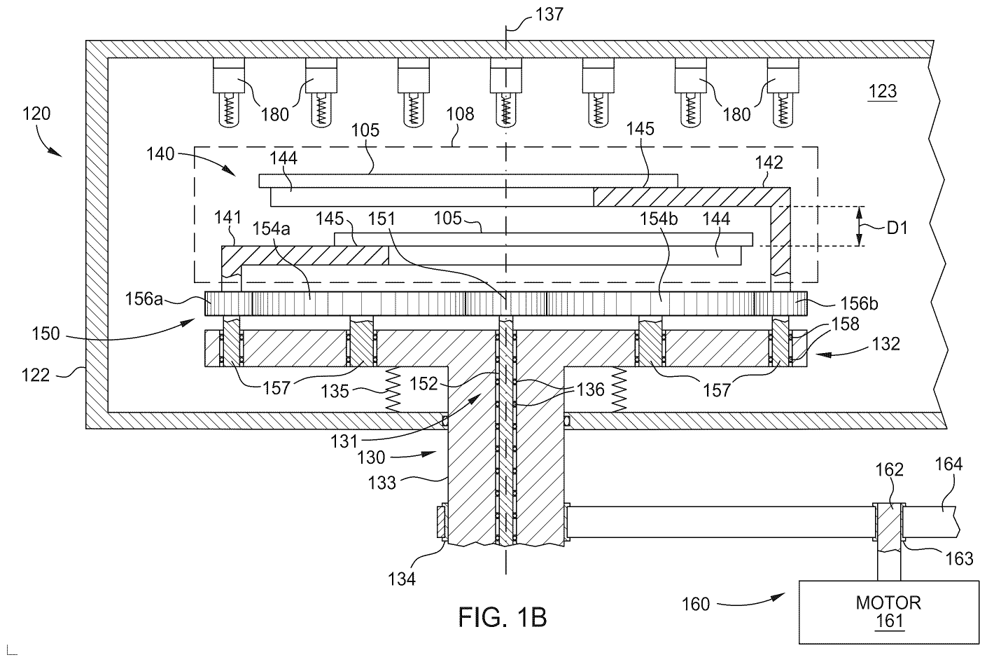

FIG. 1A illustrates a schematic plan view of a cluster tool 100. The cluster tool 100 includes a factory interface 102, two substrate processing chambers 110, a substrate swapper assembly 120, two load locks 170, and a controller 190. The load locks 170 and processing chambers 110 are in pairs, with each pair having one load lock 170 opposing a corresponding processing chamber 110. The substrate swapper assembly 120 is located between the processing chambers 110 and the load locks 170. The substrate swapper assembly 120 includes a swapper 130 for each pair of the processing chambers 110 and load locks 170, and each swapper 130 is used to swap the substrates 105 in the corresponding processing chamber 110 and load lock 170. The cluster tool 100 may also include a vacuum assembly 107 that is used to create and/or maintain a pressure within the cluster tool 100, such as the pressure within each processing chamber 110, the swapper assembly 120, and each load lock 170.

The factory interface 102 may be coupled to one or more front opening unified pods (FOUPs) 103. FOUPs 103 may each be a container having a stationary cassette therein for holding multiple substrates. FOUPs 103 may each have a front opening interface configured to be used with factory interface 102. Factory interface 102 may have a buffer chamber (not shown) and one or more robot assemblies (not shown) configured to transfer substrates via linear, rotational, and/or vertical movement between FOUPs 103 and the load locks 170.

The processing chambers 110 include a substrate support 112 (e.g., pedestal, platen) and a processing kit and source assembly configured to process the substrate 105 within the processing chamber 110. The processing chambers 110 may perform any number of processes such as preclean, PVD, CVD, ALD, decoupled plasma nitridation (DPN), rapid thermal processing (RTP), and etching. In one embodiment, the processing sequence is adapted to form a high-K capacitor structure, where processing chambers 110 may be a DPN chamber, a CVD chamber capable of depositing poly-silicon, and/or a MCVD chamber capable of depositing titanium, tungsten, tantalum, platinum, or ruthenium. The substrate support 112 may include one or more lift pins to lift and lower the substrate 105 relative to the substrate support 112, such as using the lift pins to transfer the substrate 105 to or from the swapper 130. In some embodiments, a slit valve 114 is located between the processing chamber 110 and the swapper assembly 120. When the slit valve 114 is in an open position, the swapper 130 is allowed to enter the processing chamber 110. When the slit valve 114 is in the closed position, the processing chamber 110 is isolated from the swapper assembly 120. In some embodiments, the slit valve 114 is omitted.

Each load lock 170 may have a first slit valve 171 and a second slit valve 172. When the first slit valve 171 is open, a substrate 105 can be transferred from the factory interface 102 and to support members, such as lift pins, positioned in the load lock 170. When the first slit valve 171 is closed, the interior of the load lock 170 is isolated from the factory interface 102. Thus, the load locks 170 provide a vacuum interface between the factory interface 102 (e.g., front-end environment) and the remainder the cluster tool 100. When the second slit valve 172 is open, the swapper 130 is allowed to enter the load lock 170 where the substrate 105 is then transferred to the swapper 130. When the second slit valve 172 is closed, the interior of the load lock 170 is isolated from the swapper assembly 120 and the processing chambers 110. In some embodiments, there is only one load lock 170 that is configured to receive each swapper 130.

FIGS. 1A and 1B illustrate the swapper assembly 120, with FIG. 1B showing a schematic partial cross-sectional view of the swapper assembly 120. The swapper assembly 120 additionally includes a housing 122 and a motor assembly 160 coupled to the swappers. The housing 122 defines an internal swapper chamber 123 that comprises an internal region that has an internal volume in which the swappers 130 are disposed. The swappers 130 are partially disposed in the swapper chamber 123, and the substrates pass through the swapper chamber 123 between the load locks 170 and the processing chamber 110. In some embodiments, each swapper 130 is operated by the same motor assembly 160 which is located outside of the swapper chamber 123, such as being disposed underneath the swapper chamber 123 as shown in FIG. 1A. In some embodiments, a wall of the housing 122 bifurcates the swapper chamber 123 such that each swapper 130 is isolated from the other.

Each swapper 130 includes a body 131 that includes an upper portion 132 and a shaft 133 that extends downward from the upper portion 132. The shaft 133 includes a body pulley 134 that is coupled to the shaft 131 that is coupled to the body 131. A bellows assembly 135 may be disposed around the shaft 133 to seal the swapper chamber 123 from the outside environment while facilitating the rotation of the body 131 relative to the housing 122. The upper portion 132 supports an arm assembly 140 and a gear assembly 150 of the swapper 130. The arm assembly 140 includes a first arm 141 (e.g., left arm) and a second arm 142 (e.g., right arm) that are rotated by the gear assembly 150. The arms 141, 142 are moveable to extended positions where each arm 141, 142 is located within either the load lock 170 or the processing chamber 110 to convey a substrate 105 disposed on the arm 141, 142. FIG. 1A shows the first arm 141 in an extended position, with the first arm 141 positioned within the processing chamber 110 above the substrate support 112 while the second arm 142 is shown in an extended positioned within the load lock 170. The arms 141, 142 are moved to swap positions, such that the first arm 141 is moved to an extended position within the load lock 170 while the second arm 142 is moved to an extend position within the processing chamber 110. The arms 141, 142 may also be moved to a retracted position (FIG. 1B) where the arms 141, 142 overlap one another.

The arms 141, 142 each include a support 144 with a substrate support surface 145. The support 144 is also referred to herein as a blade. As shown in FIG. 1A, the support 144 may have a fork shape. The substrate 105 is placed into engagement with the substrate support surface 145 of the support 144. The support 144 carries the substrate 105 disposed thereon as the swapper 130 moves the substrate 105 between the load lock 170 and the processing chamber 110. As shown in FIG. 1B, the support 144 of the first arm 141 and second arm 142 are located at different heights such that one arm can pass underneath the other arm without the substrate 105 on the lower arm contacting the upper arm. As shown, the first arm 141 is located at a height above the upper portion 132 that is lower than the second arm 142. A distance, shown as D1, is present between the substrate support surface 145 of the support 144 of the first arm 141 and the underside of the second arm 142. This distance D1 is sized to allow the substrate 105 to pass underneath the second arm 142 without contacting the second arm 142. Additionally, the opening between the load lock 170 and the swapper assembly 120 that can be covered by the second slit valve 172 is sized to allow the arms 141, 142 to enter and exit the load lock 170 without the arms 141, 142 or the substrate 105 disposed thereon contacting a surface of the opening. The opening (shown as dashed opening 108) between the processing chamber 110 and the swapper assembly 120 that can be covered by the slit valve 114 is also sized to allow the arms 141, 142 to enter and exit the processing chamber 110 without the arms 141, 142 or the substrate 105 disposed thereon contacting a surface of the opening.

FIG. 1A shows a substrate 105 placed on the support 144 of each arm 141, 142. A portion of each arm 141, 142 is shown in dashed to illustrate that the substrate 105 is supported on the corresponding arm 141, 142. An illustrative trajectory point 147 is shown for each support 144. The trajectory point 147 will follow the trajectory 146 as the motor assembly 160 operates the swapper 130 to move the arms 141, 142. The trajectory point 147 is shown being between the two forks of the support 144, but the trajectory point 147 may be located at a point on the substrate support surface 145 depending on the shape of the support 144. As shown in FIG. 1A, the trajectory 146 (shown as a line) is a substantially linear path that extends from the center point of the substrate support 112, over the central axis 137 of the swapper 130, to a center point of the load lock 170. In other words, this illustrative point 147 moves linearly as the first arm 141 and second arm 142 swap positions. The substrate 105 disposed on the support 144 of each arm 141, 142 similarly moves in a linear fashion. Thus, the swapper 130 is used to move the substrates in a linear trajectory between the load lock 170 and processing chamber 110, and vice versa. In other words, the actuation of the motor(s) 161 within the motor assembly 160 causes the substrate support surface 144 of the first arm 141 and a substrate support surface 144 of the second arm 142 to translate along a linear trajectory. The arms 141, 142 move the substrate 105 disposed thereon along parallel linear trajectories that are separated by a distance since each arm is located at a different height. And, as shown in FIG. 1A, each pair of processing chambers 110 and load locks 170 are positioned opposing each other across the swapper assembly 120 such that the linear trajectory of the substrates 105 moved by one swapper 130 is parallel to the linear trajectory of the substrates 105 moved by the other swapper 130.

The gear assembly 150 includes a central gear 151, a first idler gear 154a, a second idler gear 154b, and a first arm gear 156a, and a second arm gear 156b. The first arm 141 is attached to the first arm gear 156a and the second arm 142 is attached to the second arm gear 156b. The central gear 151 is shown as stationary. For example, the central gear 151 may be fixed on a shaft 152 that extends through the upper portion 132 and the shaft 133 of the body 131. The body 131 may include one or more bearing elements 136 to facilitate the rotation of the body 131 relative to the stationary shaft 152. The bearing elements 136 may be a ball bearing, a spherical roller bearing, or other bearing element suitable to facilitate rotation between the body 131 and the shaft 152. The idler gears 154a,b and arm bears 156a,b may be mounted on a shaft 157 that is coupled to the upper portion 132. For example, a plurality of bearing elements 158 are embedded in the upper portion 132 to facilitate the rotation of the shaft 157, and thus the rotation of the gear attached to the corresponding shaft 157, relative to the body 131. In some embodiments, the shaft 157 is fixed to the body 131 and a plurality of bearing elements 158 are disposed around the shaft 157 between the corresponding gear and the shaft 157.

FIG. 1B shows the motor assembly 160 connected with one swapper 130, which is representative of the connection of the motor assembly 160 with the other swapper 130 shown in FIG. 1A. In some embodiments, the motor assembly 160 includes a single motor 161 that rotates an output shaft 162. In other words, the motor assembly 160 includes one, and only one, motor 161 to operate multiple swappers 130 instead of using different motor to operate each swapper. The output shaft 162 includes a motor pulley 163 that is coupled to the output shaft 162. A belt 164 is connected to the motor pulley 163 and loops around the body pulley 134 of each swapper 130. The belt 164 transfers rotational power from the motor pulley 163 to each body pulley 134, which causes the body 131 to rotate about a central axis 137 of the swapper 130. In some embodiments, the motor 161 may be an electrical, hydraulic, or pneumatic motor. In some embodiments, the body pulleys 134 and motor pulley 163 may each have a groove that corresponds with the shape of the belt 164. In some embodiments, the body pulleys 134 and motor pulley 163 may each have teeth that interface with the teeth of the belt 164. In some embodiments, the belt 164 may be substituted for a chain, with the motor pulley 163 and body pulleys 134 being substituted for a sprocket that interfaces with the chain.

As the body 131 rotates, the idler gears 154a,b rotate (e.g., orbit) around the stationary central gear 151. The central gear 151 has teeth that interface with corresponding teeth on the idler gears 154a,b. The engagement of the central gear 151 with the orbiting idler gears 154a,b causes the idler gears 154a,b to rotate relative to the body 131 in a first direction. These idler gears 154a,b also have teeth that interface with the teeth of the arm gears 156a,b to cause the arm gears 156a,b to rotate relative to the body 131 in a second direction. The rotation of the arm gears 156a,b causes the corresponding arm 141, 142 attached thereto to rotate relative to the body 131.

The gear ratio of the gear assembly 150 is configured to achieve a desired shape and resolution of the path (e.g., linear movement) in which the substrate 105 is transferred between the load lock 170 and processing chamber 110. In some embodiments, the gear ratio for the central gear 151 to the arm gears 146a,b is a 1:2 ratio to achieve the linear movement of the substrate 105 by moving the point 147 of the support 144 along the linear trajectory 146 as shown in FIG. 1A. In other words, one full orbit of an idler gear 154a,b around the central gear 151 causes the corresponding arm gear 146a,b to rotate twice.

The controller 190 can be in communication with the motor assembly 160 to control the position of the arms 141, 142 of the swappers 130. Operating the two swappers 130 with the same motor assembly 160 allows both swappers 130 to be moved in a synchronous fashion. In some embodiments, the swappers 130 are arranged as shown in FIG. 1A where the arms 141, 142 of one swapper 130 move synchronously with the corresponding arm 141, 142 of the other swapper 130. In some embodiments, the swappers 130 are offset to one another. For example, one swapper 130 may have both arms 141, 142 in an extended position while the arms 141, 142 of the other swapper 130 are positioned in the retracted position.

In some embodiments, the swapper assembly 120 is also a pre-heater such that the temperature of the substrates 105 is increased prior to the substrate being placed into the processing chamber 110. One or more heat sources 180 may be disposed within the swapper chamber 123 above each swapper 130 that are used to increase the temperature of the substrates 105. In some embodiments, the one or more heat sources 180 may be disposed outside of the swapper chamber 123 and be configured to deliver radiant heat through a window (not shown) to each swapper 130 disposed within the internal region of the swapper chamber 123. The heat sources 180 discussed herein include radiant heat sources configured to deliver radiation to the internal region of the swapper chamber 123, such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The motor assembly 160 may be operated move the substrates 105 through the swapper chamber 123 over a period of time sufficient to heat the substrates 105 to a desired temperature. For example, the motor assembly 160 may be used to pause (e.g., stop) the movement of the swappers 130 while the substrates 105 are positioned in the swapper chamber 123 underneath the heat sources 180 for a period of time.

In some embodiments, the motor assembly 160 includes a second belt. The shaft 162 includes a second pulley and the central gear 151 is coupled to a pulley. The second belt is extends from the second pulley of the shaft 162 to the pulley coupled to the central gear 151 to rotate the central gear 151 relative to the body 131.

In some embodiments, the cluster tool includes three or more pairs of load locks 170 and processing chambers 110, and one swapper assembly 120 with a swapper 130 located between each pair of load locks 170 and processing chambers 110. The same motor assembly 160 is used to operate each swapper 130, such as three or more swappers 130. For example, the swapper assembly 120 may have four swappers 130 driven by the same motor assembly 160.

The actuation of one or more motors of the motor assembly 160 causes the position of the first arm 141 and second arm 142 of each swapper 130 to change position simultaneously. In some embodiments, the motor assembly 160 includes a separate motor to drive the operation an individual swapper 130. For example, two separate motors may be exterior of the housing 122 of the swapper assembly 120, each motor used to drive a different swapper 130. Each motor may have an output shaft 162 with a motor pulley 162 to drive a belt 164 that loops around a body pulley 134 coupled to a shaft 133 of one of the swappers 130. In some embodiments, each motor is operated synchronously to allow for the synchronized operation of the swappers 130. In other words, the motor assembly 160 may move the swappers 130 in a synchronous fashion using a separate motor for each swapper 130.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the cluster tool 100, to facilitate control of the cluster tool 100. For example, in one or more embodiments the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the cluster tool 100. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods (such as operations 401-412) and operations disclosed herein may generally be implemented under the control of the CPU of the controller 190 by the CPU executing computer instruction code stored in the memory (or in memory of a particular processing chamber) as, e.g., a software routine. When the computer instruction code is executed by the CPU, the CPU controls the components of the cluster tool 100 to conduct operations in accordance with the various methods and operations described herein. In one or more embodiments, the memory (a non-transitory computer readable medium) includes instructions stored therein that, when executed, cause the methods (such as the operations 401-412) and operations (such as the operations 401-412) described herein to be conducted. The operations described herein can be stored in the memory in the form of computer readable logic.

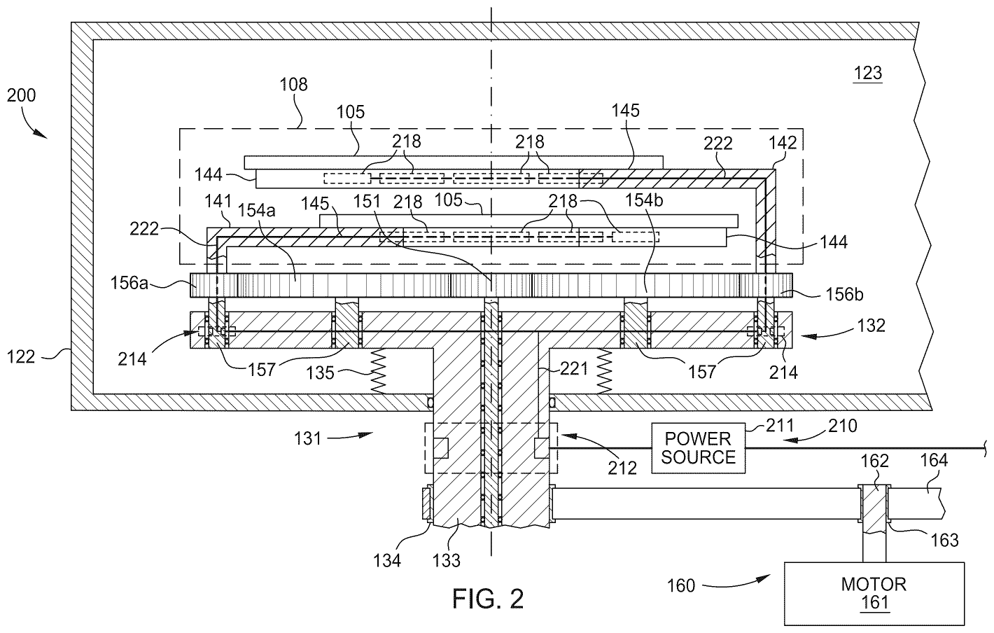

FIG. 2 illustrates a schematic partial cross-sectional view of a swapper assembly 200 which may be substituted for the swapper assembly 120 of the cluster tool 100. The swapper assembly 200 has similar components as the swapper assembly 120 as indicated by the reference signs without reciting the description of these components of the swapper assembly 120 for brevity.

Rather than including a plurality of heat sources above the swappers 130, the swapper assembly 200 pre-heats the substrates 105 by heating the arms 141, 142 using a pre-heat assembly 210. The pre-heat assembly 210 includes a power source 211, a first rotary electrical connector 212 coupled to the shaft 133, second rotary electrical connectors 214 coupled to the upper portion 132, and one or more heating elements 218 disposed in the support 144 of each arm 141, 142. In some embodiments, the one or more heating elements 218 are a plurality of heating elements. FIG. 2 is representative of the other swappers 130 with a pre-heat assembly 210 of the swapper assembly 200, and each pre-heat assembly 210 of the multiple swappers 130 may share the same power source 211.

The power source 211 may be a direct current (DC) power supply and the first rotary electrical connector 212 may be a slip ring having a plurality of brush connections or a roll ring connector. Electrical power is transferred from the first rotary electrical connector 212 to the second rotary electrical connectors 214 by a first wire 221. The second rotary electrical connectors 214 may also be a slip ring having a plurality of brush connections or a roll ring connector. The second rotary electrical connectors 214 are shown coupled to the shaft 157 of each arm gear 156a,b. Electrical power is transferred from each second rotary electrical connector 214 to the heating elements 218 in a corresponding arm 141, 142 by a second wire 222. In other words, the heating elements 218 in a respective arm 141, 142 receive power through the first rotary electrical connectors 212 and respective second rotary electrical connector 214 that is coupled to the arm 141, 142 that includes the heating elements 218.

The support 144 of each arm 141, 142 may be made of a ceramic material. The plurality of heating elements 218 are embedded in the support 144. For example, the heating elements 218 may be resistive heating elements. Electrical power supplied to the heating elements 218 is used to generate heat, which is transferred to the substrate 105 in contact with the support 144. The support 144 may be sized such that a majority of the underside of the substrate 105 is in direct contact with the substrate support surface 145 to more evenly heat the substrate 105. In some embodiments, more than 80% of the surface area of the underside of the substrate 105 is in contact with the substrate support surface 145. The support 144 may have a plurality of slots or openings to allow a corresponding lift pin of the processing chamber 110 to access the underside of the substrate 105 that is being pre-heated on the support 144.

In some embodiments, the pre-heat assembly 210 has one second rotary electrical connection 212 that is connected to heating elements 218 embedded in one of the arms 141, 142. For example, the swapper 130 may be operated such that the one of the arms 141, 142 conveys unprocessed substrate 105 to the processing chamber while the other arm 141, 142 is used to convey processed substrates 105. Thus, the arm conveying the unprocessed substrates 105 may be the arm having heating elements 218 embedded therein.

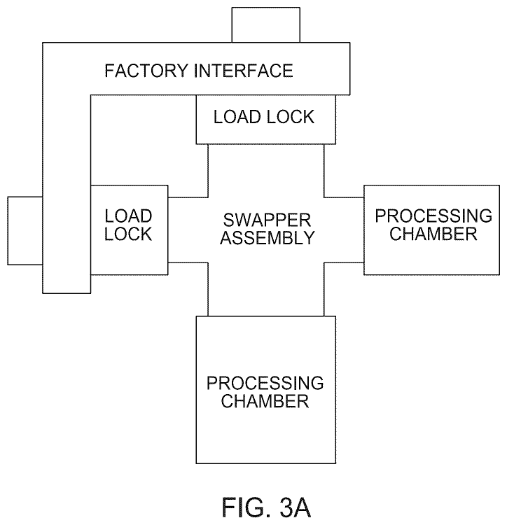

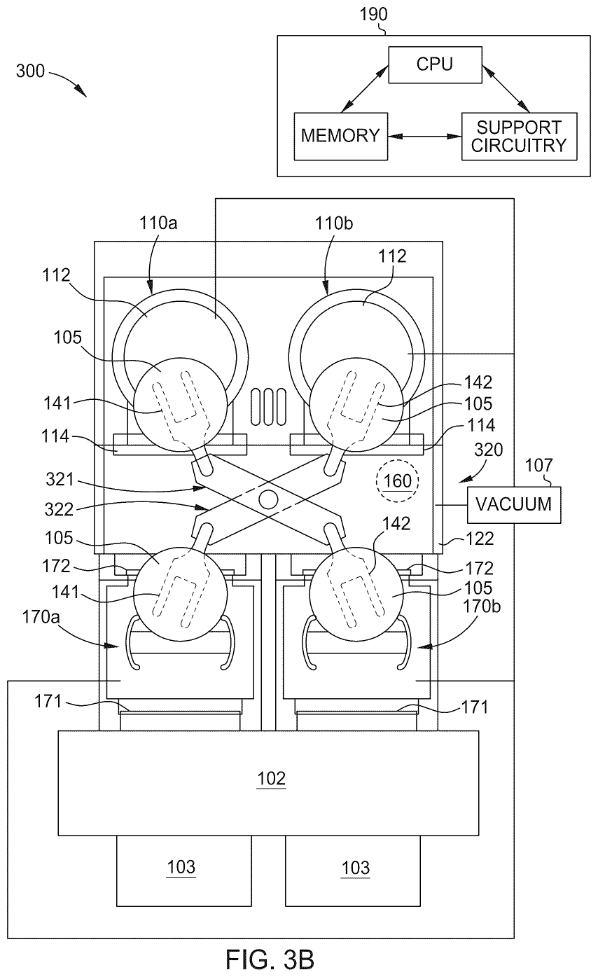

In some embodiments, a cluster tool has a first load lock separated from a first processing chamber by a swapper assembly and a second load lock separated from a second processing chamber by the swapper assembly. The first load lock and the first processing chamber are not arranged parallel to the second load lock and the second processing chamber. Instead, the second load lock and the second processing chamber are arranged at a diagonal relative to the first load lock and the first processing chamber, as shown in schematic FIG. 3A. The swapper assembly includes a first swapper to swap substrates between the first load lock and the first processing chamber and a second swapper to swap substrates between the second load lock and the second processing chamber. The first swapper and the second swapper each have two arms each configured to swap a substrate disposed thereon along a linear trajectory located at different planes. The first swapper and the second swapper are arranged such that the linear trajectories of the first and second arms of the first swapper are at an angle (e.g., diagonal) relative to the linear trajectories of the first and second arms of the second swapper. In other words, the trajectories of the arms of the first swapper and the second swapper cross one another (e.g., are not parallel to one another), but the trajectories may be located at different heights to avoid contact between the arms. The same motor assembly is used to operate both swappers.

In some embodiments, a cluster tool has a first load lock separated from a first processing chamber by a swapper assembly and a second load lock separated from a second processing chamber by the swapper assembly. The first load lock and the first processing chamber are not arranged parallel to the second load lock and the second processing chamber. Instead, the second load lock and the second processing chamber are arranged at a diagonal relative to the first load lock and the first processing chamber, as shown in schematic FIG. 3A. The swapper assembly includes a swapper with a first pair of arms to swap substrates between the first load lock and the first processing chamber and a second pair of arms to swap substrates between the second load lock and the second processing chamber. The first pair of arms are configured to swap the substrates disposed thereon along parallel trajectories separated by a distance. The second pair of arms are configured to swap the substrates disposed thereon along parallel trajectories separated by a distance. The trajectories of the second pair of arms are disposed at an angle, but are not co-planar, to the trajectories of the first pair of arms. In other words, the trajectories of the arms of the first swapper and the second swapper cross one another (e.g., are not parallel to one another), but the trajectories may be located at different heights to avoid contact between the arms. The same motor assembly is used to operate both swappers.

FIG. 3B illustrates a schematic plan view of a cluster tool 300. The cluster tool 300 similar components as cluster tool 100 as indicated by the reference signs without reciting the description of these components for brevity. The cluster tool 300 is illustrated with a first load lock 112a, a second load lock 112b, a first processing chamber 110a, and a second processing chamber 110b to facilitate the explanation of the cluster tool 300.

The cluster tool 300 includes a swapper assembly 320 that includes a first swapper 321 that is located above a second swapper 322. The first swapper 321 may be rotationally offset from the second swapper 322. The first swapper 321 and second swapper 322 may each be swapper 130. One or more heat sources may be disposed in the swapper assembly 320. In some embodiments, the first and second swappers 321, 322 may each be the swapper 130 that includes a pre-heat assembly 210. In some embodiments, the first swapper 321 is inverted as compared to the second swapper 322. The swappers 321, 322 are able to operate to transfer substrates without contacting one another.

In some embodiments, the same motor assembly 160 with one motor operates the first swapper 321 and the second swapper 322. In other words, the same motor operates the first and second swapper 321, 322. In some embodiments, the motor assembly 160 includes separate motors, each motor driving a separate swapper 321, 322. Both motors may be operated synchronously due to one or more commands sent from the system controller such that both swappers 321, 322 are operated in a synchronous fashion.

In some embodiments, the swapper assembly 320 is configured such that the first arm 141 of first swapper 321 and the first arm 141 of the second swapper 322 each swap substrates 105 in linear trajectory between first load lock 112a to the first processing chamber 110a. The swapper assembly 320 is further configured such that the second arms 142 of the first swapper 321 and second swapper 322 each swap substrates 105 in a linear trajectory between second load lock 112b to the second processing chamber 110b.

In some embodiments, the swapper assembly 320 is configured such that the first and second arms 141, 142 of the first swapper 321 swaps substrates between the first processing chamber 110a and the second load lock 170b. The swapper assembly 320 is further configured such that the first and second arms 141, 142 of the second swapper 322 swaps substrates between the second processing chamber 110b and the first load lock 170a. In other words, the first and second swappers 321, 322 are arranged to convey substrates along crossing trajectories at different heights such that the first and second swappers 321, 322 to not contact one another.

In some embodiments, the first slit valves 171 may be disposed at an angle such that the a robot of the factory interface 102 is able to enter the load locks, 170a, 170b at an angle such that the robot is aligned with the corresponding arm 141, 142 of the first and second swappers 321, 322. In other words, the first slit valves 171, 172 may be arranged to allow the robot to be positioned between the forks of the arm, such as the first arm 141, when positioned in the corresponding load lock 170a, 170b.

In some embodiments, a cluster tool includes two or more cluster tools 300 integrated together. For example, each cluster tool 300 sharing a common housing or factory interface. The two or more cluster tools 300 have one swapper assembly 320 with a common housing 122 that includes multiple pairs of first swappers 321 and second swappers 322. For example, the cluster tool may have four load locks 170, four processing chambers 110, and one swapper assembly 320 may have two pairs of first and second swappers 321, 322.

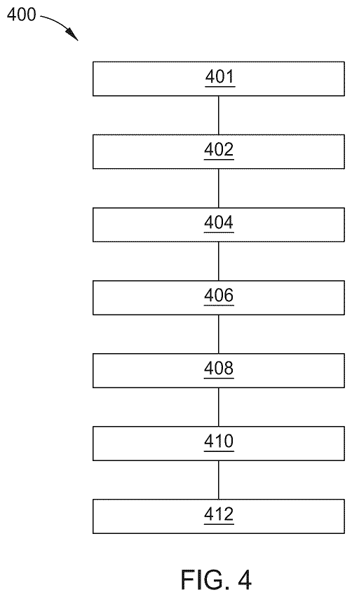

FIG. 4 illustrates a flow chart of an exemplary method 400 of operating a cluster tool, such as cluster tool 100.

At operation 401, a robot of the factory interface 102 may place a substrate 105, such as a non-processed substrate, in the load lock 170 through the open first slit valve 171 prior to the swapper 130 placing an arm, such as the second arm 142, into the load lock 170. The substrate 105 may be placed on one or more support members, such as lift pins, within the load lock 170. The robot of the factory interface may be used to align the center of the substrate 105 in a desired position within the load lock 170. This desired position may be selected based on the desired position of the center of the substrate 105 relative to the support 144 when the substrate 105 is transferred to an arm 141, 142, such as the second arm 142. For example, the centers of the load lock 170 and processing chamber 110 may be slightly offset. The robot of the factory interface 102 places the substrate 105 in position within the load lock 170 such that the center of the substrate 105, after being retrieved by the second arm 142, will be aligned with the center of the substrate support 112 when the second arm 142 is moved to the processing chamber 110. The load lock 170 is then least partially evacuated by the vacuum assembly 107 while the first slit valve 171 and second slit valve 172 are closed to decrease the pressure within the load lock 170. For example, the vacuum assembly 107 may be used to equalized pressure within the interior of the load lock 170 with the pressure within the swapper chamber 123.

At operation 402, at least two swappers 130 are operated such that each swapper 130 has a first arm 141 disposed in an extended position within a processing chamber 110 and a second arm 142 disposed in an extended position within a load lock 170. The substrate 105 positioned within the load lock 170 is then transferred to the support 144 of the second arm 142. For example, the substrate 105 may be supported on lift pins within the load lock 170 that are lowered after the second arm 142 is placed in load lock 170 to transfer the substrate 105 onto the support 144 of the second arm 142. The slit valves 114 are opened to accommodate the insertion of the first arm 142 into the processing chamber 110 and the slit valve 172 is opened to accommodate the movement of the second arm 142 into the load lock 170.

At operation 404, lift pins of a processing chamber 110 retract to lower a processed substrate 105 supported on the lift pins into engagement with the substrate support surface 145 of the support 144 of each first arm 141. The lift pins are extended to lift the substrate 105 to a position above the substrate support 112 prior to operation 402 to allow each first arm 141 to move below the raised substrate 105. Operation 404 may occur before, after, or simultaneously with operation 404. Operation 404 may take more or less time to complete than operation 402.

At operation 406, the motor assembly 160 causes the at least two swappers 130 to swap the positions of the arms 141, 142. Each second arm 142 is now located in the corresponding processing chamber 110 while each first arm 141 is located in the corresponding load lock 170. The unprocessed substrate 105 on each first arm 141 may be pre-heated as the position of the arms 141, 142 are swapped. The slit valves 114 and 172 are open while the arms 141, 142 swap positions.

At operation 408, each substrate 105 supported on the second arm 142 above the substrate support 112 within the processing chamber 110 is disengaged from the support 144 by extending the lift pins. The movement of the lift pins can accommodate the difference in heights of the supports 144 of the arms 141, 142. Each substrate 105 supported on the first arm 141 is removed therefrom by the support members, such as lift pins, within the load lock 170.

At operation 410, the motor assembly 160 is operated to move the arms 141, 142 of each swapper 130 to the retracted position. The lift pins in the processing chamber 110 are retracted to engage the substrate 105 with the substrate support 112. The substrate 105 is then processed within the processing chamber 110. The slit valves 114, 171, 172, may be closed while the substrate 105 is processed. Additionally, the first slit valve 171 is opened, while the second slit valve 172 is closed, to allow a robot of the factory interface 102 to retrieve the processed substrate 105 from the load lock 170. The robot of the factory interface 102 then places the substrate 105 into a FOUP 103.

At operation 412, the motor assembly 160 is operated to continue to rotate each swapper 130 to position the second arm 142 back into the load lock 170 and to position the first arm 141 back into the processing chamber 110 after the substrate is processed while the substrate 105 is positioned above the substrate support 112 on lift pins. The method 400 may then repeat.

In some embodiments, the swapper may not have a body 131 and a gear assembly 150 as shown in FIGS. 1A-1B and in FIG. 2. Instead, the swapper may be a parallelogram linkage that is rotatable by the motor assembly 160 to swap the arms 141, 142.

While the foregoing is directed to embodiments of the present disclosure, other and further embodiments of the disclosure may be devised without departing from the basic scope thereof, and the scope thereof is determined by the claims that follow.

What is claimed is:

1. A swapper assembly, comprising:
a housing comprising an internal region;
at least two swappers at least partially disposed within the internal region of the housing, each swapper including a body, a first arm, a second arm, and wherein
the body is rotatable relative to the housing, and
the first arm and second arm are rotatable relative to the body; and
a motor assembly coupled to the at least two swappers, wherein actuation of one or more motors within the motor assembly causes the position of the first arm and second arm of each of the at least two swappers to simultaneously change.

2. The swapper assembly of claim 1, wherein:
each swapper of the at least two swappers comprises:
a first pulley coupled to the body; and
the motor assembly further comprises:
a second pulley coupled to a shaft of the motor; and
a belt coupling the first pulley of each swapper to the second pulley.

3. The swapper assembly of claim 1, further comprising:
one or more heat sources configured to deliver radiation to the internal region, wherein the one or more heat sources comprise a radiant heat source.

4. The swapper assembly of claim 1, further comprising:
a pre-heat assembly comprising:
a power supply; and
a plurality of heating elements disposed in the first arm and the second arm of each of the at least two swappers, wherein the plurality of heating elements receive electrical power from the power supply through a first rotary electrical connector coupled to the first arm and a second rotary electrical connector coupled to the second arm.

5. The swapper assembly of claim 1, wherein the actuation of the motor within the motor assembly causes a substrate support surface of the first arm and a substrate support surface of the second arm to translate along a linear trajectory.

6. The swapper assembly of claim 1, further comprising:
a gear assembly including:
a stationary central gear, wherein the body is rotatable relative to the central gear;
a first idler gear and a second idler gear connected to the body, wherein the first and second idler gears orbit the stationary central gear as the body rotates relative to the central gear; and
a first arm gear attached to the first arm and a second arm gear attached to the second arm, wherein the first arm gear is rotatable in response to the rotation of the first idler gear to rotate the first arm, and wherein the second arm gear is rotatable in response to the rotation of the second idler gear to rotate the second arm.

7. The swapper assembly of claim 6, further comprising:
a pre-heat assembly including:
a power supply; and
a plurality of heating elements disposed in the first arm and the second arm of each of the at least two swappers, wherein the plurality of heating elements receive electrical power from the power supply through a first rotary electrical connector coupled to the first arm and a second rotary electrical connector coupled to the second arm.

8. The swapper assembly of claim 6, wherein a gearing ratio between the stationary central gear and the first arm gear and the stationary central gear and the second arm gear is 1:2.

9. The swapper assembly of claim 1, wherein the at least two swappers comprise four swappers.

10. The swapper assembly of claim 1, wherein the one or more motors of the motor assembly is a single motor that is configured to drive both the first swapper and the second swapper.

11. A method of operating a cluster tool, comprising:
placing a first substrate on a first arm of a first swapper, the first arm being positioned in a first load lock;
placing a second substrate on a second arm of the first swapper, the second arm being positioned within a first processing chamber;
placing a third substrate on a third arm of a second swapper, the third arm being located in a second load lock;
placing a fourth substrate on a fourth arm of the second swapper, the fourth arm being positioned within a second processing chamber; and
actuating the first swapper and the second swapper simultaneously to move the first substrate on the first arm into the first processing chamber, the second substrate on the second arm into the first load lock, the third substrate on the third arm into the second processing chamber, and the fourth substrate on the fourth arm into the second load lock.

12. The method of claim 11, wherein the first substrate on the first arm moves in a first linear trajectory and the third substrate on the third arm moves in a second linear trajectory, wherein the first linear trajectory is parallel to the second linear trajectory.

13. The method of claim 11, wherein the first swapper and the second swapper are operated by the same motor.

14. The method of claim 11, further comprising:
pre-heating the first substrate and the third substrate during the operation of the first swapper and the second swapper.

15. The method of claim 14, wherein the pre-heating includes supplying electricity to heating elements embedded in the first arm of the first swapper and the third arm of the second swapper.

16. The method of claim 11, further comprising:
removing the first substrate from the first arm in the first processing chamber and removing the third substrate from the third arm in the second processing chamber; and
operating the first swapper to move the first arm and the second arm to a retracted position simultaneously with operating the second swapper to move the third arm and fourth arm to a retracted position using the same motor.

17. A cluster tool, comprising:
a first load lock and a second load lock;
a first processing chamber and second processing chamber;
a swapper assembly disposed between the first load lock and the first processing chamber and between the second load lock and the second processing chamber, the swapper assembly including:
a housing;
first swapper at least partially disposed within the housing and rotatable relative to the housing, the first swapper including a first arm and a second arm, wherein the first arm is moveable to convey a first substrate disposed thereon along a first trajectory from the first load lock to the first processing chamber, and the second arm is moveable to convey a second substrate disposed thereon along a second trajectory from the first processing chamber to the first load lock;
a second swapper at least partially disposed within the housing and rotatable relative to the housing, the second swapper including a third arm and a fourth arm, wherein the third arm is moveable to convey a third substrate disposed thereon along a third trajectory from the second load lock to the second processing chamber, and the fourth arm is moveable to convey a fourth substrate disposed thereon along a fourth trajectory from the second processing chamber to the second load lock; and
a motor assembly configured to operate the first swapper and second swapper simultaneously to move the first arm and second arm of the first swapper and the third arm and fourth arm of the second swapper.

18. The cluster tool of claim 17, wherein the motor assembly includes one, and only one motor to drive the operation of the first swapper and the second swapper.

19. The cluster tool of claim 17, wherein the first trajectory and the second trajectory are parallel to the third trajectory and the fourth trajectory.

20. The cluster tool of claim 17, further comprising:
a plurality of heat sources disposed in the housing above the first swapper and the second swapper.
